(19) United States
(12) Patent Application Publication
(10) Pub. No.: US 2023/0344413 A1
(43) Pub. Date: Oct. 26, 2023

(54) FILTER DEVICE

(71) Applicant: Murata Manufacturing Co., Ltd., Nagaokakyo-shi (JP)

(72) Inventor: Minefumi OUCHI, Nagaokakyo-shi (JP)

(21) Appl. No.: 18/214,591

(22) Filed: Jun. 27, 2023

Related U.S. Application Data
(63) Continuation of application No. PCT/JP2021/048304, filed on Dec. 24, 2021.
(60) Provisional application No. 63/130,989, filed on Dec. 28, 2020.

(51) Int. Cl. H03H 9/56; H03H 9/205; H03H 9/54

(52) U.S. Cl. CPC H03H 9/568; H03H 9/205; H03H 9/542

(57) ABSTRACT

A filter device includes a first series arm resonator in a series arm, and a first parallel arm resonator in a parallel arm, each of the first series arm resonator and the first parallel arm resonator is defined by an acoustic wave resonator including a piezoelectric layer made of lithium niobate or lithium tantalate and at least a first electrode and a second electrode on the piezoelectric layer. The acoustic wave resonator satisfies a condition of d/p being equal to or less than about 0.5, when a thickness of the piezoelectric layer is d and a distance between centers of the first and second electrodes adjacent to each other is p. An inductor connected in series to the first series arm resonator is between the first series arm resonator and the first parallel arm resonator.

### CROSS REFERENCE TO RELATED APPLICATIONS

This application claims the benefit of priority to Provisional Application No. 63/130,989 filed on Dec. 28, 2020 and is a Continuation application of PCT Application No. PCT/JP2021/048304 filed on Dec. 24, 2021. The entire contents of each application are hereby incorporated herein by reference.

### BACKGROUND OF THE INVENTION

### 1. Field of the Invention

The present invention relates to a filter device including an acoustic wave resonator that includes lithium niobate or lithium tantalate.

### 2. Description of the Related Art

Conventionally, a band pass filter device including a plurality of acoustic wave resonators is widely used. For example, in a filter device disclosed in Japanese Unexamined Patent Application Publication No. 2021-093710, an acoustic wave resonator including a piezoelectric layer made of lithium niobate or lithium tantalate is disclosed.

In the filter device described in Japanese Unexamined Patent Application Publication No. 2021-093710, there is a problem that an attenuation in an attenuation band on a higher frequency side than a pass band is easily deteriorated.

### SUMMARY OF THE INVENTION

Preferred embodiments of the present invention provide filter devices in each of which deterioration of an attenuation on a higher frequency side than a pass band is less likely to occur.

According to a preferred embodiment of the present invention, a filter device includes a first series arm resonator in a series arm connecting an input terminal and an output terminal, and a first parallel arm resonator in a parallel arm connecting the series arm and a ground potential, each of the first series arm resonator and the first parallel arm resonator includes an acoustic wave resonator including a piezoelectric layer made of lithium niobate or lithium tantalate and at least one pair of a first electrode and a second electrode on the piezoelectric layer, the acoustic wave resonator satisfying a condition of d/p being equal to or less than about 0.5, when a film thickness of the piezoelectric layer is defined as d and a distance between centers of the first electrode and the second electrode adjacent to each other is defined as p, and an inductor connected in series to the first series arm resonator is provided between the first series arm resonator and the first parallel arm resonator.

According to preferred embodiments of the present invention, it is possible to provide filter devices in each of which deterioration of an attenuation on a higher frequency side than a pass band is less likely to occur.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a circuit diagram of a filter device according to a first preferred embodiment of the present invention.

FIG. 2 is a diagram illustrating attenuation-frequency characteristics of the filter device according to the first preferred embodiment of the present invention.

FIG. 3 is a diagram illustrating a relationship between a fractional band width (%) and an attenuation in a 5G Wifi band.

FIG. 4 is a diagram illustrating S21 bandpass characteristics in a filter device according to a comparative example.

FIG. 5 is a diagram illustrating impedance characteristics of respective resonators in the filter device according to the comparative example.

FIG. 6 is a diagram illustrating S21 bandpass characteristics in the filter device according to the first preferred embodiment of the present invention.

FIG. 7 is a diagram illustrating impedance characteristics of a plurality of acoustic wave resonators used in the filter device according to the first preferred embodiment of the present invention.

FIG. 8 is a schematic configuration diagram of the filter device according to the first preferred embodiment of the present invention.

FIG. 9 is a schematic configuration diagram of a modified example of the filter device according to the first preferred embodiment of the present invention.

FIG. 10 is a diagram illustrating attenuation-frequency characteristics of a filter including a plurality of acoustic wave resonators other than acoustic wave resonators defining a wideband band pass filter.

FIG. 11 is a diagram illustrating attenuation-frequency characteristics of the wideband band pass filter.

FIG. 12 is a circuit diagram of a filter device according to a second preferred embodiment of the present invention.

FIGS. 13A and 13B are a schematic perspective view illustrating an appearance of an acoustic wave device that utilizes a thickness shear mode, and a plan view illustrating an electrode structure on a piezoelectric layer, respectively.

FIG. 14 is a cross-sectional view of a portion taken along a line A-A in FIG. 13A.

FIG. 15A is a schematic elevational cross-sectional view for explaining a Lamb wave propagating through a piezoelectric film of a conventional acoustic wave device, and FIG. 15B is a schematic elevational cross-sectional view for explaining vibration of an acoustic wave device that utilizes the thickness shear mode.

FIG. 16 is a diagram for explaining an amplitude direction of a bulk wave in a thickness shear mode.

FIG. 17 is a diagram illustrating resonance characteristics of an acoustic wave device that utilizes the thickness shear mode.

FIG. 18 is a diagram illustrating a relationship between d/2p when a distance between centers of electrode fingers that are adjacent to each other is defined as p and a thickness of the piezoelectric layer is defined as d, and a fractional band width in defining and functioning as a resonator.

FIG. 19 is a plan view illustrating an acoustic wave device that uses a bulk wave in the thickness shear mode.

FIG. 20 is a diagram illustrating a map of a fractional band width with respect to Euler angles (0°, θ, ψ) of LiNbO₃ when d/p is made as close to 0 as possible.

FIG. 21 a diagram illustrating a relationship among d/2p, a metallization rate MR, and a fractional band width.

### DETAILED DESCRIPTION OF THE PREFERRED EMBODIMENTS

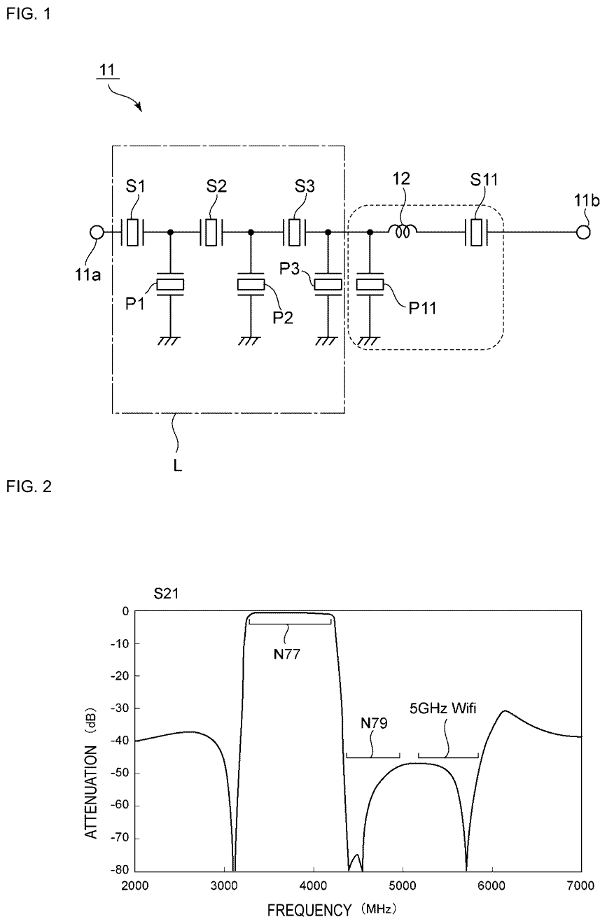

FIG. 1 is a circuit diagram of a filter device according to a first preferred embodiment of the present invention.

A filter device 11 includes a series arm connecting an input terminal 11a and an output terminal 11b, and a plurality of parallel arms connected between the series arm and a ground potential. In the series arm, a plurality of series arm resonators S1, S2, and S3 and a first series arm resonator S11 are connected in series.

A parallel arm resonator P1 is provided in the parallel arm connecting a connection point between the series arm resonator S1 and the series arm resonator S2 and the ground potential. A parallel arm resonator P2 is provided in the parallel arm connecting the ground potential and a connection point between the series arm resonator S2 and the series arm resonator S3. A parallel arm resonator P3 is provided in the parallel arm connecting the ground potential and a connection point between the series arm resonator S3 and the first series arm resonator S11. The series arm resonators S1 to S3 and the parallel arm resonators P1 to P3 are used to constitute a filter including a ladder-type circuit L.

Further, an inductor 12 and the first series arm resonator S11 are connected in series between the filter including the ladder circuit L and the output terminal 11b. The first parallel arm resonator P11 is provided so as to connect a connection point between the series arm resonator S3 and the inductor 12 to the ground potential.

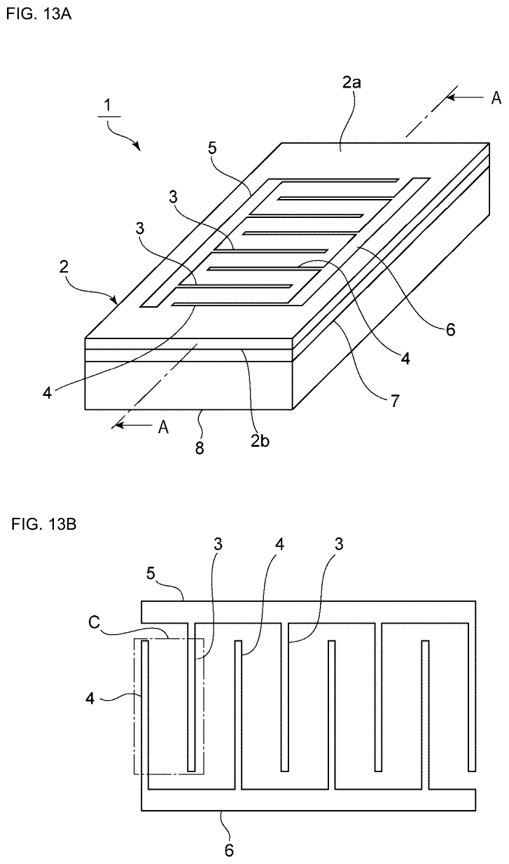

The plurality of series arm resonators S1 to S3, the plurality of parallel arm resonators P1 to P3, the first series arm resonator S11, and the first parallel arm resonator P11 are defined by acoustic wave resonators. As the acoustic wave resonator, an acoustic wave device 1, which will be described later, is used. In the acoustic wave resonator defined by the acoustic wave device 1, favorable resonance characteristics using a bulk wave in a thickness shear mode are obtained, which will be described later. That is, a high coupling coefficient can be obtained, and a fractional band width can be widened. In addition, a Q value can be increased. These specific features of the acoustic wave device 1 will be described in detail later with reference to FIG. 13 to FIG. 21.

In the filter device 11, a plurality of acoustic wave resonators defined by the acoustic wave devices 1 described above are used, and the first series arm resonator S11, the first parallel arm resonator P11, and the inductor 12 that have been described above are provided. Thus, it is possible to sufficiently increase the attenuation in the attenuation band on the higher frequency side than the pass band, and to improve attenuation characteristics.

The filter device 11 according to the present preferred embodiment is, for example, a band pass filter for the N77 band to be used in 5G of a smartphone. In the N77 band, the pass band is from about 3300 MHz to about 4200 MHz. In the N77 band, the band width ((an edge portion of the pass band on the higher frequency side−an edge portion of the pass band on the lower frequency side)/a center value of a bandwidth) accounts for ((4200−3300)/3750×100=)24%, which is very large.

FIG. 2 is a diagram illustrating attenuation-frequency characteristics of the filter device 11 according to the first preferred embodiment. As is apparent from FIG. 2, the attenuation is substantially 0 in the pass band of the N77 band. In the vicinity of the N77 band, the pass band of the N79 band and the pass band of the 5 GHz Wi-Fi exist on the higher frequency side. The pass band of the N79 band is from about 4.4 MHz to about 4.9 GHz. The pass band of 5 GHz Wi-Fi is from about 5170 MHz to about 5835 MHz.

Thus, the filter device 11 for the N77 band is required to have a sufficiently large attenuation in the pass band of the N79 band and the pass band of 5G Wi-Fi.

Thus, in the band pass filter of the N77 band, a large attenuation is required on the higher frequency side than the pass band. To be specific, for example, when the center frequency is set to Fc, a sufficiently large attenuation needs to be ensured within a wide frequency range of from about 1.17 Fc to about 1.6 Fc. The same applies to a band pass filter for the N79 band.

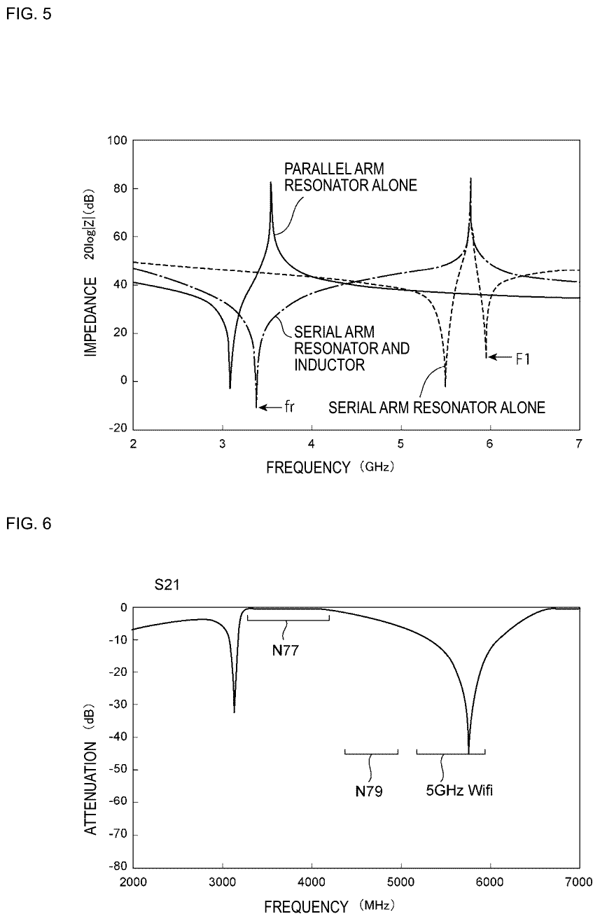

FIG. 4 is a diagram illustrating S21 bandpass characteristics in a filter device according to a comparative example as a conventional example, and FIG. 5 is a diagram illustrating impedance characteristics of respective resonators thereof. In the case of a conventional pass band filter including a plurality of acoustic wave resonators, a fractional band width of each acoustic wave resonator is about 3% to about 6%, which is relatively narrow. Thus, in order to configure a filter device having a wide fractional band width such as N77, an inductor having a large inductance needs to be inserted in a path connecting the parallel arm resonator and the series arm resonator.

In this case, as illustrated in FIG. 5, a resonance point F1 that appears due to the insertion of the inductor approaches an anti-resonance point of the series arm resonator of the pass band. Thus, a band pass filter may be provided in the vicinity of the attenuation band on the higher frequency side than the pass band, that is, in the vicinity of a band of, for example, 5 GHz Wi-Fi. This makes the attenuation small on the higher frequency side than the pass band, which may deteriorate the attenuation in the pass band of the N79 band or 5 GHz Wi-Fi.

On the other hand, in the filter device 11, as illustrated in FIG. 2, the attenuation in the attenuation band on the higher frequency side than the pass band is made sufficiently large. This will be described with reference to FIG. 6 to FIG. 11.

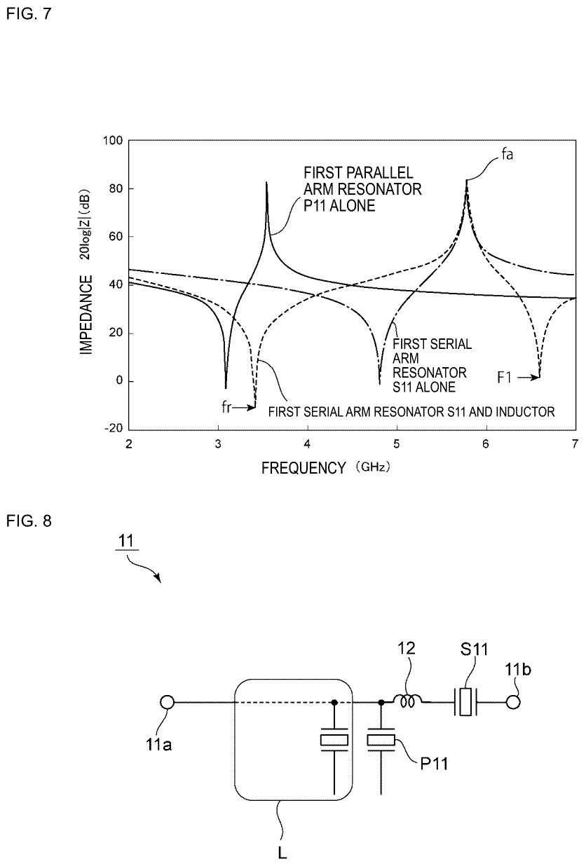

FIG. 6 is a diagram illustrating S21 bandpass characteristics in the filter device 11 according to the first preferred embodiment of the present invention, and FIG. 7 is a diagram illustrating impedance characteristics of a plurality of acoustic wave resonators used in the filter device 11.

In the filter device 11, the acoustic wave device 1 that uses the thickness shear mode is used. In this case, the fractional band width accounts for about 20%, which is relatively large. According to this, in the filter device 11 including a plurality of acoustic wave devices 1, the inductance of the inductor 12 inserted in series in the path connecting the first series arm resonator S11 and the first parallel arm resonator P11 may be small. Thus, as illustrated in FIG. 7, the resonance point F1 generated by the insertion of the inductor 12 is positioned on a sufficiently higher frequency side than an anti-resonance point fa of the first series arm resonator S11. According to this, in the filter device 11, the attenuation in the attenuation band on the higher frequency side than the pass band is less likely to be adversely affected. As a result, as illustrated in FIG. 2, the attenuation on the higher frequency side than the pass band is made sufficiently large.

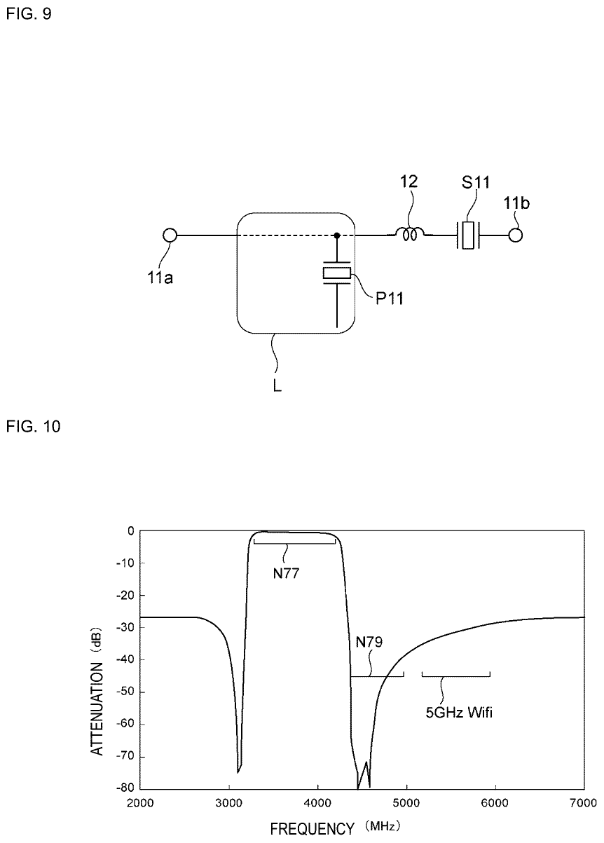

FIG. 8 and FIG. 9 are a schematic configuration diagram of the filter device 11 according to the first preferred embodiment of the present invention and a schematic configuration diagram of a modified example of the filter device 11 according to the first preferred embodiment. As illustrated in FIG. 8, in the filter device 11, the ladder circuit L including a plurality of acoustic wave resonators is connected between the input terminal 11a and the output terminal 11b. The inductor 12 and the first series arm resonator S11 are connected between the ladder circuit L and the output terminal 11b in the series arm. Then, the inductor 12 is connected in series to a path connecting the first series arm resonator S11 and the first parallel arm resonator P11. In other words, as in the modified example illustrated in FIG. 9, the first parallel arm resonator P11 may be the parallel arm resonator closest to the output terminal 11b of the ladder circuit L. Even in this case, the inductor 12 is only required to be connected in series to the path connecting the first parallel arm resonator P11 and the first series arm resonator S11.

In any case, in the filter device 11, since the plurality of acoustic wave resonators are defined by the acoustic wave devices 1, which will be described later, a fractional band width of the acoustic wave resonators is increased as described above. Thus, as described above, since only a small inductance of the inductor 12 is required, it is possible to sufficiently increase the attenuation in the attenuation band on the higher frequency side than the pass band.

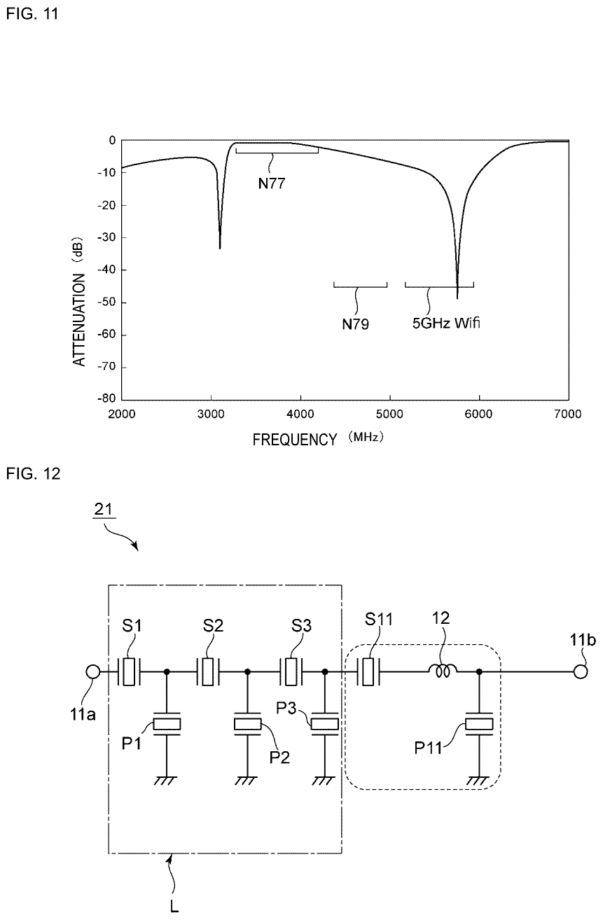

FIG. 10 is a diagram illustrating attenuation-frequency characteristics of a filter including a plurality of acoustic wave resonators other than acoustic wave resonators defining a wideband band pass filter. That is, FIG. 10 is a diagram illustrating attenuation-frequency characteristics of only a portion defined by the above-described ladder filter. Characteristics obtained by adding these filter characteristics with the attenuation-frequency characteristics of the band pass filter illustrated in FIG. 11 correspond to the attenuation-frequency characteristics of the filter device 11 illustrated in FIG. 2. That is, FIG. 11 illustrates attenuation-frequency characteristics of a band pass filter constituted by the first series arm resonator S11, the first parallel arm resonator P11, and the inductor 12 that have been described above.

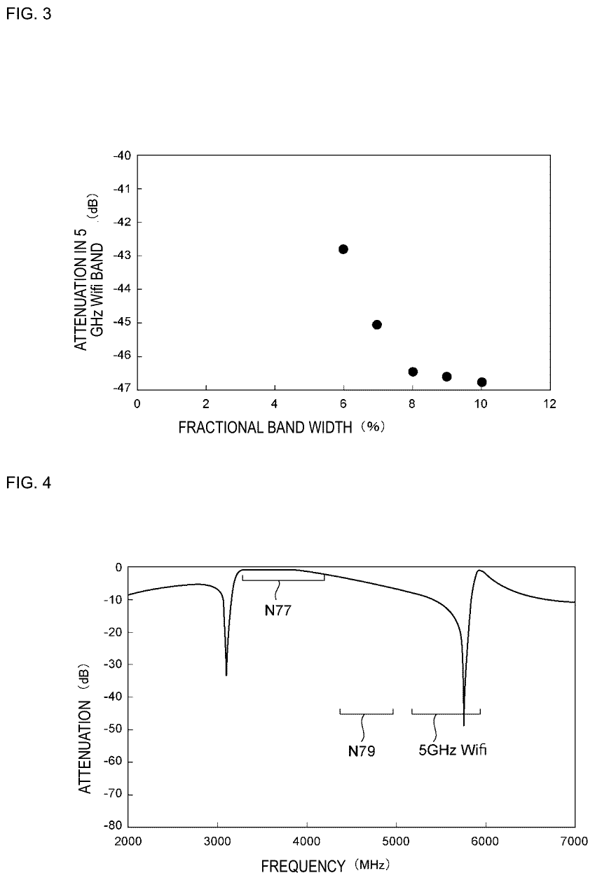

Preferably, in order to increase an attenuation in the 5 GHz Wi-Fi band, a fractional band width of the series arm resonator is, for example, equal to or larger than about 6%, and more preferably equal to or larger than about 8%. As illustrated in FIG. 3, when the fractional band width is equal to or larger than about 6%, the attenuation in the 5 GHz Wi-Fi band can be sufficiently increased, and when the fractional band width is equal to or larger than about 8%, the attenuation can be further increased.

The 5 GHz Wi-Fi band has a lower limit of Ch32: about 5150 MHz to about 5170 MHz and an upper limit of Ch173: about 5855 MHz to about 5875 MHz.

FIG. 12 is a circuit diagram of a filter device according to a second preferred embodiment of the present invention. In the filter device 21, the plurality of series arm resonators S1 to S3, the first series arm resonator S11, and the inductor 12 are connected in series to each other in the series arm connecting the input terminal 11a and the output terminal lib. Further, the parallel arm resonators P1 to P3 are provided in a manner similar to those in the filter device 11. A difference from the filter device 11 is that the first series arm resonator S11 and the inductor 12 are connected in series in this order on the output terminal lib side of a portion of the ladder filter. In addition, the first parallel arm resonator P11 is connected to a ground potential and a connection point between the inductor 12 and the output terminal lib. As described above, the connection order of the first series arm resonator S11 and the first parallel arm resonator P11 may be reversed from that in the filter device 11.

In the filter device 11, the fractional band width is preferably, for example, equal to or more than 10%. Thus, it is suitably used as a band pass filter for Band N77 or Band N79.

In addition, in the present invention, providing the first series arm resonator, the first parallel arm resonator, and the inductor is only required, but a plurality of parallel arm resonators are preferably provided in a plurality of parallel arms connecting the series arm and the ground potential. In this case, the first parallel arm resonator described above is provided in one parallel arm. More preferably, the first parallel arm resonator is a parallel arm resonator closest to the first series arm resonator among the plurality of parallel arm resonators.

Further, in a preferred embodiment of the present invention, a plurality of series arm resonators including the first series arm resonator described above are provided in the series arm. In this case, it is preferable that the first series arm resonator is the series arm resonator closest to the input terminal 11a or the output terminal 11b among the plurality of series arm resonators.

Furthermore, an anti-resonant frequency of the first series arm resonator S11 is preferably higher than anti-resonant frequencies of the remaining series arm resonators S1 to S3. This can sufficiently increase the attenuation on the higher frequency side than the pass band.

As described above, a filter device according to a preferred embodiment of the present invention includes the first series arm resonator, the first parallel arm resonator, and the other series arm resonators and parallel arm resonators that are provided as necessary, and these resonators are preferably provided on the same substrate. Alternatively, the first series arm resonator may be provided on a substrate different from a substrate on which the remaining series arm resonators, among the plurality of series arm resonators, excluding the first series arm resonator are provided. In this case, since two or more chips are provided, a film configuration can be easily changed. Thus, an adjustment range of characteristics such as a fractional band width and a TCF (Temperature coefficient of frequency) can be widened. In the filter device 11, among the plurality of series arm resonators S1 to S3 and the first series arm resonator S11, the remaining series arm resonators S1 to S3 excluding the first series arm resonator S11 and the plurality of parallel arm resonators P1 to P3 define a ladder circuit defining a pass band. Then, the first series arm resonator S11, the first parallel arm resonator P11, and the inductor 12 define a band pass filter.

An acoustic wave device that uses a bulk wave in a thickness shear mode, in which an acoustic wave device according to a preferred embodiment of the present invention is preferably used, will be described below. A support in the following example corresponds to a support substrate in a preferred embodiment of the present invention.

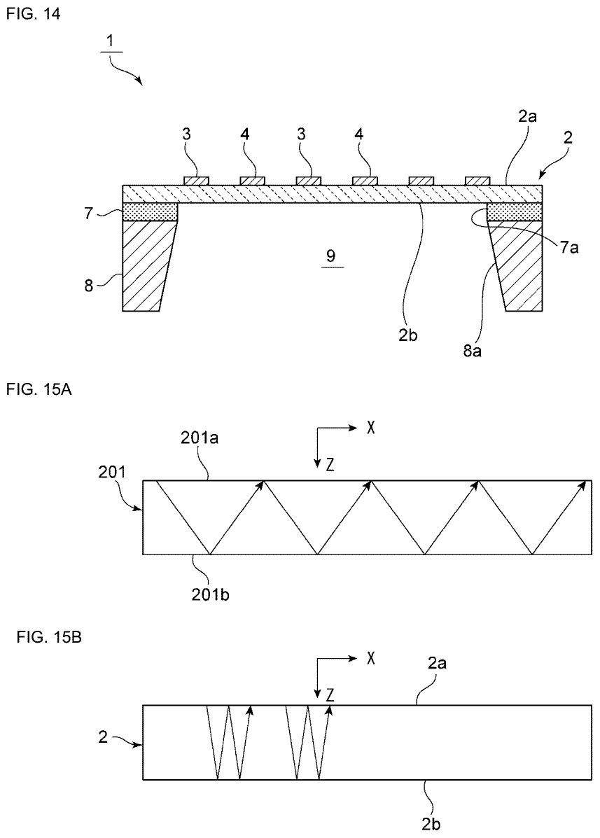

FIG. 13A is a schematic perspective view illustrating an appearance of an acoustic wave device that uses a bulk wave in a thickness shear mode, FIG. 13B is a plan view illustrating an electrode structure on a piezoelectric layer, and FIG. 14 is a cross-sectional view of a portion taken along a line A-A in FIG. 13A.

The acoustic wave device 1 includes the piezoelectric layer 2 made of, for example, LiNbO₃. The piezoelectric layer 2 may be made of, for example, LiTaO₃. Cut angles of LiNbO₃ and LiTaO₃ are Z-cut, but may be rotated Y-cut or X-cut. In order to effectively excite the thickness shear mode, a thickness of the piezoelectric layer 2 is not particularly limited, but is preferably, for example, equal to or more than about 40 nm and equal to or less than about 1000 nm, and more preferably equal to or more than about 50 nm and equal to or less than about 1000 nm. The piezoelectric layer 2 includes the first and second main surfaces 2a and 2b that are opposed to each other. The electrode finger 3 and the electrode finger 4 are provided on the first main surface 2a. In FIGS. 13A and 13B, a plurality of electrode fingers 3 are connected to a first busbar 5. A plurality of electrode fingers 4 are connected to a second busbar 6. The plurality of electrode fingers 3 and the plurality of electrode fingers 4 are interdigitated with each other. Each of the electrode finger 3 and the electrode finger 4 has a rectangular or substantially rectangular shape and a length direction. In a direction orthogonal or substantially orthogonal to the length direction, the electrode finger 3 and the electrode finger 4 adjacent to the electrode finger 3 face each other. Both the length direction of the electrode fingers 3 and 4 and the direction orthogonal or substantially orthogonal to the length direction of the electrode fingers 3 and 4 are directions intersecting the thickness direction of the piezoelectric layer 2. Thus, it can also be said that the electrode finger 3 and the electrode finger 4 adjacent to the electrode finger 3 face each other in the direction intersecting the thickness direction of the piezoelectric layer 2. Further, the length direction of the electrode fingers 3 and 4 may be changed to the direction orthogonal or substantially orthogonal to the length direction of the electrode fingers 3 and 4 illustrated in FIGS. 13A and 13B. That is, in FIGS. 13A and 13B, the electrode fingers 3 and 4 may extend in a direction in which the first busbar 5 and the second busbar 6 extend. In this case, the first busbar 5 and the second busbar 6 extend in the direction in which the electrode fingers 3 and 4 extend in FIGS. 13A and 13B. Additionally, a plurality of pairs of structures in which the electrode finger 3 connected to one potential and the electrode finger 4 connected to the other potential are adjacent to each other is provided in the above-described direction orthogonal or substantially orthogonal to the length direction of the electrode fingers 3 and 4. Here, the fact that the electrode finger 3 and the electrode finger 4 are adjacent to each other does not refer to a case where the electrode finger 3 and the electrode finger 4 are disposed so as to be in direct contact with each other, but refers to a case where the electrode finger 3 and the electrode finger 4 are disposed with a gap therebetween. Additionally, when the electrode finger 3 and the electrode finger 4 are adjacent to each other, an electrode connected to a hot electrode or a ground electrode, in addition to the other electrode fingers 3 and 4, is not disposed between the electrode finger 3 and the electrode finger 4. The number of pairs does not need to be integer pairs, but may be 1.5 pairs, 2.5 pairs, or the like. A distance between centers of the electrode fingers 3 and 4, that is, a pitch is preferably within a range being equal to or more than about 1 μm and equal to or less than about 10 μm, for example. In addition, widths of the electrode fingers 3 and 4, that is, dimensions of the electrode fingers 3 and 4 in a facing direction, are preferably, for example, within a range being equal to or more than about 50 nm and equal to or less than about 1000 nm, and more preferably within a range being equal to or more than about 150 nm and equal to or less than about 1000 nm. The distance between the centers of the electrode fingers 3 and 4 is a distance connecting a center of a dimension (width dimension) of the electrode finger 3 in the direction orthogonal or substantially orthogonal to the length direction of the electrode finger 3 and a center of a dimension (width dimension) of the electrode finger 4 in the direction orthogonal or substantially orthogonal to the length direction of the electrode finger 4.

In addition, since the acoustic wave device 1 uses the piezoelectric layer of Z-cut, the direction orthogonal or substantially orthogonal to the length direction of the electrode fingers 3 and 4 is a direction orthogonal or substantially orthogonal to a polarization direction of the piezoelectric layer 2. This does not apply to a case where a piezoelectric material having another cut angle is used as the piezoelectric layer 2. Here, the term “orthogonal” is not limited to being strictly orthogonal but may be substantially orthogonal (an angle between the direction orthogonal to the length direction of the electrode fingers 3 and 4 and the polarization direction is within a range of about 90°±10°, for example).

A support 8 is laminated on the second main surface 2b side of the piezoelectric layer 2 with an insulating layer 7 interposed therebetween. The insulating layer 7 and the support 8 have a frame shape, and include cavities 7a and 8a as illustrated in FIG. 14. Thus, an air gap portion 9 is provided in order not to interfere with vibration of an excitation region C of the piezoelectric layer 2. Thus, the support 8 described above is laminated on the second main surface 2b with the insulating layer 7 interposed therebetween at a position not overlapping with a portion where at least one pair of electrode fingers 3 and 4 are provided. The insulating layer 7 does not need to be provided. Thus, the support 8 can be directly or indirectly laminated on the second main surface 2b of the piezoelectric layer 2.

The insulating layer 7 is made of, for example, silicon oxide. Alternatively, in addition to silicon oxide, an appropriate insulating material such as, for example, silicon oxynitride or alumina may be used. The support 8 is made of, for example, Si. A plane orientation of a surface made of Si on the piezoelectric layer 2 side may be (100), (110), or (111). Si of the support 8 preferably has, for example, a high resistance equal to or higher than a resistivity of about 4 kΩ. The support 8 can also be made using an appropriate insulating material or semiconductor material.

Examples of a material of the support 8 include piezoelectric materials such as aluminum oxide, lithium tantalate, lithium niobate, and crystal, various ceramics such as alumina, magnesia, sapphire, silicon nitride, aluminum nitride, silicon carbide, zirconia, cordierite, mullite, steatite, and forsterite, dielectrics such as diamond and glass, and semiconductors such as gallium nitride.

The plurality of electrode fingers 3 and 4 and the first and second busbars 5 and 6 that have been described are made of an appropriate metal or alloy such as, for example, Al or an AlCu alloy. In the present preferred embodiment, the electrode fingers 3 and 4 and the first and second busbars 5 and 6 have a structure including an Al film laminated on a Ti film. An adhesion layer other than the Ti film may be used.

At the time of driving, an alternating current voltage is applied between the plurality of electrode fingers 3 and the plurality of electrode fingers 4. More specifically, an alternating current voltage is applied between the first busbar 5 and the second busbar 6. Thus, it is possible to obtain resonance characteristics using a bulk wave in a thickness shear mode excited in the piezoelectric layer 2. Additionally, in the acoustic wave device 1, when the thickness of the piezoelectric layer 2 is defined as d and a distance between centers of the electrode fingers 3 and 4 that are adjacent to each other and that are any one pair among the plurality of pairs of electrode fingers 3 and 4 is defined as p, d/p is, for example, less than or equal to about 0.5. According to this, the bulk wave in the thickness shear mode described above is effectively excited, and good resonance characteristics can be obtained. More preferably, for example, d/p is equal to or less than about 0.24, and in this case, even better resonance characteristics can be obtained.

Since the acoustic wave device 1 has the above-described configuration, even when the number of pairs of the electrode fingers 3 and 4 is reduced in order to achieve a reduction in size, a decrease in Q value is less likely to occur. This is because a propagation loss is small even when the number of electrode fingers in the reflectors on both sides is reduced. In addition, the number of electrode fingers can be reduced by utilizing the bulk wave in the thickness shear mode. A difference between the Lamb wave used in the acoustic wave device and the bulk wave in the thickness shear mode described above will be described with reference to FIGS. 15A and 15B.

FIG. 15A is a schematic elevational cross-sectional view for explaining a Lamb wave propagating through a piezoelectric film of an acoustic wave device as described in Japanese Unexamined Patent Application Publication No. 2021-093710. Here, a wave propagates through the inside of a piezoelectric film 201 as indicated by an arrow. Here, the piezoelectric film 201 includes a first main surface 201a and a second main surface 201b that are opposed to each other, and a thickness direction connecting the first main surface 201a and the second main surface 201b is a Z direction. An X direction is a direction in which electrode fingers of an IDT electrode are arranged. As illustrated in FIG. 15A, as for the Lamb wave, a wave propagates in the X direction. Although the piezoelectric film 201 vibrates as a whole because the Lamb wave is a plate wave, since the wave propagates in the X direction, reflectors are arranged on both sides to obtain resonance characteristics. Thus, a propagation loss of the wave occurs, and a Q value decreases when the size is reduced, that is, when the number of pairs of electrode fingers is reduced.

On the other hand, as illustrated in FIG. 15B, in the acoustic wave device 1, since vibration displacement occurs in a thickness shear direction, the wave propagates substantially in the direction connecting the first main surface 2a and the second main surface 2b of the piezoelectric layer 2, that is, in the Z direction, and resonates. That is, an X-direction component of the wave is significantly smaller than a Z-direction component. Moreover, since resonance characteristics are obtained by the propagation of the wave in the Z direction, a propagation loss hardly occurs even when the number of electrode fingers of the reflectors is reduced. Furthermore, even when the number of pairs of electrode fingers constituted by the electrode fingers 3 and 4 is reduced in order to further reduce the size, a decrease in Q value hardly occurs.

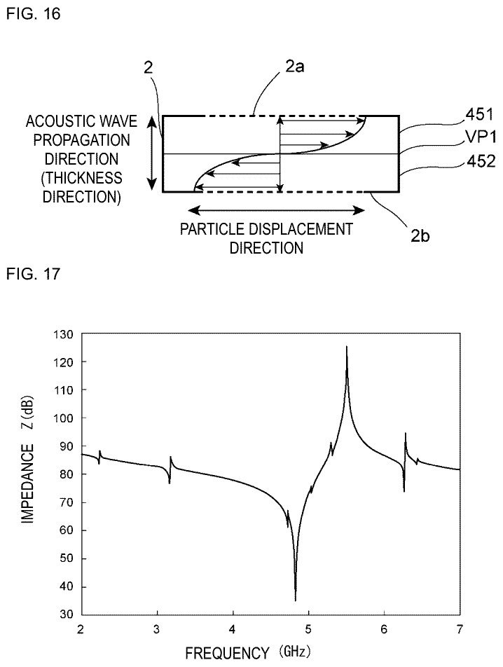

As illustrated in FIG. 16, an amplitude direction of the bulk wave in the thickness shear mode is opposite between a first region 451 included in the excitation region C of the piezoelectric layer 2 and a second region 452 included in the excitation region C. FIG. 16 schematically illustrates a bulk wave when a voltage is applied between the electrode finger 3 and the electrode finger 4 such that the electrode finger 4 has a higher potential than that of the electrode finger 3. The first region 451 is a region of the excitation region C between the first main surface 2a and a virtual plane VP1 that is orthogonal or substantially orthogonal to the thickness direction of the piezoelectric layer 2 and that divides the piezoelectric layer 2 into two portions. The second region 452 is a region of the excitation region C between the virtual plane VP1 and the second main surface 2b.

As described above, in the acoustic wave device 1, at least one pair of electrodes defined by the electrode finger 3 and the electrode finger 4 are arranged. However, since a wave is not propagated in the X direction, the number of pairs of electrode fingers defined by the electrode fingers 3 and 4 does not need to be plural. That is, it is only required that at least one pair of electrodes is provided.

For example, the electrode finger 3 described above is an electrode connected to a hot potential, and the electrode finger 4 is an electrode connected to a ground potential. Alternatively, the electrode finger 3 may be connected to a ground potential and the electrode finger 4 may be connected to a hot potential. In the present preferred embodiment, as described above, at least one pair of electrodes are an electrode connected to the hot potential or an electrode connected to the ground potential, and a floating electrode is not provided.

FIG. 17 is a diagram illustrating resonance characteristics of the acoustic wave device illustrated in FIG. 14. Design parameters of an example of the acoustic wave device 1 having the resonance characteristics are as follows.
Piezoelectric layer 2: LiNbO₃ with Euler angles (0°, θ°, 90°), a thickness thereof is about 400 nm.

A length of a region where the electrode finger 3 and the electrode finger 4 overlap with each other when viewed in the direction orthogonal to the length direction of the electrode finger 3 and the electrode finger 4, that is, a length of the excitation region C is about 40 μm, the number of pairs of electrode fingers constituted by the electrode fingers 3 and 4 is 21, a distance between centers of the electrode fingers 3 and 4 is 3 μm, widths of the electrode fingers 3 and 4 is about 500 nm, and a condition of d/p=about 0.133 is satisfied.
Insulating layer 7: a silicon oxide film having a thickness of about 1 μm.
Support 8: Si.

The length of the excitation region C is a dimension of the excitation region C along the length direction of the electrode fingers 3 and 4.

In the present preferred embodiment, all distances between the electrode fingers included in a plurality of electrode finger pairs defined by the electrode fingers 3 and 4 are set to be equal or substantially equal to each other. That is, the electrode fingers 3 and the electrode fingers 4 are arranged at equal or substantially equal pitches.

As is clear from FIG. 17, good resonance characteristics with a fractional band width of about 12.5% are obtained, for example even though no reflector is provided.

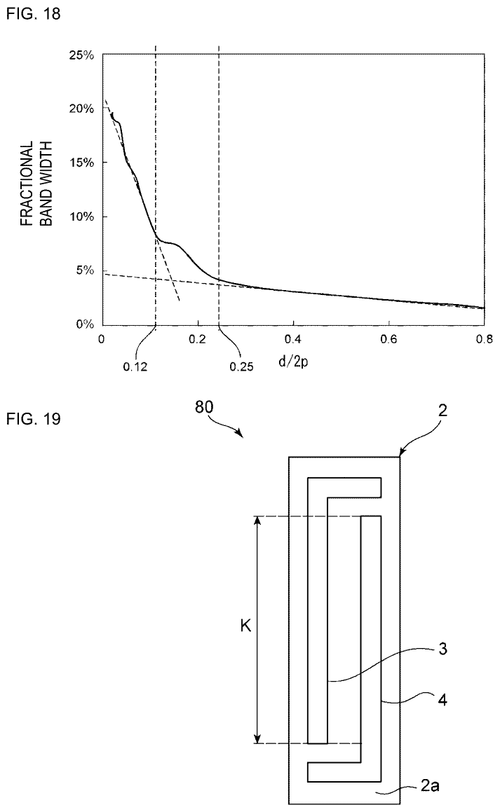

When the thickness of the piezoelectric layer 2 is defined as d and the distance between the centers of the electrode fingers 3 and 4 is defined as p, d/p is equal to or less than about 0.5, and more preferably equal to or less than about 0.24 in the present preferred embodiment as described above, for example. This will be described with reference to FIG. 18.

A plurality of acoustic wave devices are obtained in a manner similar to the acoustic wave device having the resonance characteristics illustrated in FIG. 17, except that d/2p is changed. FIG. 18 is a diagram illustrating a relationship between d/2p and a fractional band width of the acoustic wave device as a resonator.

As is apparent from FIG. 18, when d/2p exceeds about 0.25, that is, when a condition of d/p>about 0.5 is satisfied, the fractional band width is less than about 5% even when d/p is adjusted, for example. On the other hand, when a condition of d/2p≤about 0.25 is satisfied, that is, when a condition of d/p about 0.5 is satisfied, the fractional band width can be set to be equal to or more than about 5% by changing d/p within the range, for example, that is, a resonator having a high coupling coefficient can be provided. Further, when d/2p is equal to or less than about 0.12, for example, that is, when d/p is equal to or less than about 0.24, for example, the fractional band width can be increased to be equal to or more than about 7%, for example. In addition, when d/p is adjusted within this range, a resonator having a wider fractional band width can be obtained, and a resonator having a higher coupling coefficient can be provided. As a result, it is understood that by setting d/p to be equal to or less than about 0.5, for example, a resonator that has a high coupling coefficient and that uses a bulk wave in a thickness shear mode can be provided.

FIG. 19 is a plan view of an acoustic wave device that uses a bulk wave in a thickness shear mode. In an acoustic wave device 80, a pair of electrodes including the electrode fingers 3 and 4 are provided on the first main surface 2a of the piezoelectric layer 2. K in FIG. 18 is an interdigitated width. As described above, the number of pairs of electrode fingers may be one. Also in this case, when d/p described above is equal to or less than about 0.5, for example, the bulk wave in the thickness shear mode can be effectively excited.

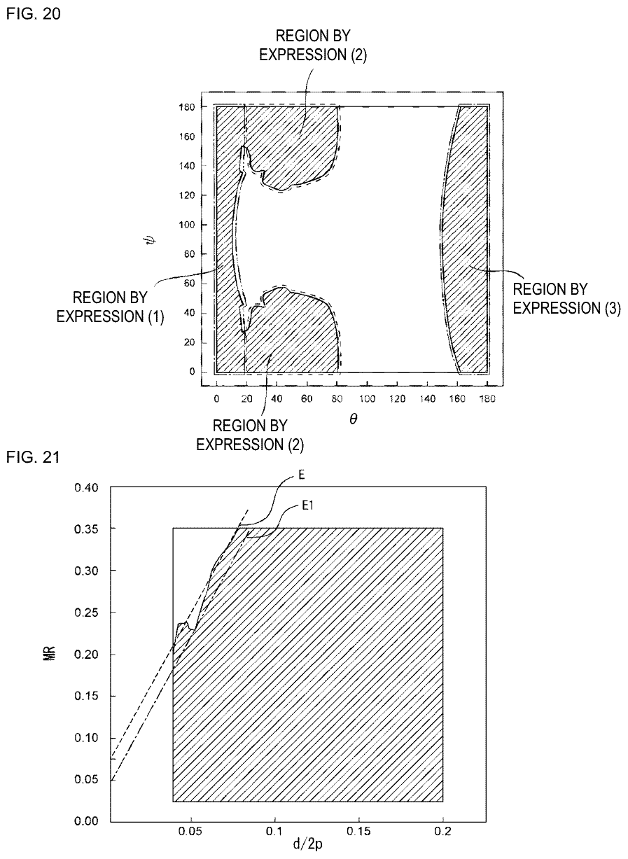

FIG. 20 is a diagram illustrating a map of a fractional band width with respect to Euler angles (0°, θ, ψ) of LiNbO₃ when d/p is brought as close to 0 as possible. A hatched portion in FIG. 20 is a region in which at least a fractional band width being equal to or more than about 5% is obtained, and when a range of the region is approximated, the range is represented by the following Expression (1), Expression (2), or Expression (3).

(0°±10°,0° to 20°, freely selected ψ) Expression(1);

(0°±10°,20° to 80°,0° to 60°(1−(θ−50)²/900)^{1/2}) or (0°±10°,20° to 80°,[180°−60°(1−(θ−50)²/900)^{1/2}] to 180° Expression(2); and

(0°±10°, [180°−30° (1−(ψ−90)²/8100)^{1/2}] to 180°, freely selected ψ) Expression (3).

Thus, in the case of the range of the Euler angles represented by the above Expression (1), Expression (2) or Expression (3), the fractional band width can be sufficiently widened, which is preferable. The same or a similar applies to the case where the piezoelectric layer 2 is a lithium tantalate layer.

FIG. 21 is a diagram illustrating a relationship among d/2p, a metallization rate MR, and a fractional band width. In the above-described acoustic wave device, various acoustic wave devices having different values of d/2p and MR are provided, and fractional band widths are measured. A hatched portion on the right side of a broken line E in FIG. 21 is a region in which the fractional band width is equal to or less than about 17%, for example. When the fractional band width is equal to or less than about 17%, for example, spurious signals can be suitably reduced by adjusting the film thickness of the piezoelectric layer 2, the dimensions of the electrode fingers 3 and 4, and the like. A boundary between the hatched region and the non-hatched region is represented by MR=about 3.5 (d/2p)+0.075, for example. That is, an equation of MR=about 1.75 (d/p)+0.075 is satisfied, for example. Thus, an expression of MR about 1.75 (d/p)+0.075 is preferably satisfied, for example. In this case, the fractional band width is likely to be equal to or less than about 17%, for example. A region on the right side of an equation of MR=about 3.5 (d/2p)+0.05 indicated by a dashed-dotted line E1 in FIG. 21 is more preferable, for example. That is, in the case of MR about 1.75 (d/p)+0.05, the fractional band width can be reliably set to be equal to or less than about 17%, for example.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A filter device comprising:
a first series arm resonator in a series arm connecting an input terminal and an output terminal; and
a first parallel arm resonator in a parallel arm connecting the series arm and a ground potential; wherein
each of the first series arm resonator and the first parallel arm resonator is an acoustic wave resonator including a piezoelectric layer made of lithium niobate or lithium tantalate, and at least one pair of a first electrode and a second electrode on the piezoelectric layer, the acoustic wave resonator satisfying a condition of d/p is equal to or less than about 0.5, when a film thickness of the piezoelectric layer is defined as d and a distance between centers of the first electrode and the second electrode adjacent to each other is defined as p; and
an inductor is connected in series to the first series arm resonator between the first series arm resonator and the first parallel arm resonator.

2. The filter device according to claim 1, wherein
a plurality of parallel arm resonators including the first parallel arm resonator are provided in the parallel arm connecting the series arm and the ground potential; and
the first parallel arm resonator is closest to the first series arm resonator among the plurality of parallel arm resonators.

3. The filter device according to claim 1, wherein
a plurality of series arm resonators including the first series arm resonator are provided in the series arm connecting the input terminal and the output terminal; and
the first series arm resonator is closest to the input terminal or the output terminal among the plurality of series arm resonators.

4. The filter device according to claim 3, wherein an anti-resonant frequency of the first series arm resonator is higher than anti-resonant frequencies of the one or more remaining series arm resonators.

5. The filter device according to claim 3, wherein the first series arm resonator has a fractional band width equal to or more than about 6%.

6. The filter device according to claim 1, wherein
a plurality of series arm resonators including the first series arm resonator are provided in the series arm connecting the input terminal and the output terminal; and
the first series arm resonator is provided on a substrate different from a substrate on which the one or more remaining series arm resonators other than the first series arm resonator among the plurality of series arm resonators are provided.

7. The filter device according to claim 2, wherein
a plurality of series arm resonators including the first series arm resonator are provided in the series arm connecting the input terminal and the output terminal;
the one or more remaining series arm resonators other than the first series arm resonator among the plurality of series arm resonators and the one or more remaining parallel arm resonators other than the first parallel arm resonator among the plurality of parallel arm resonators define a ladder circuit defining a pass band; and
the first series arm resonator, the first parallel arm resonator, and the inductor define a band pass filter.

8. The filter device according to claim 1, wherein a fractional band width of the filter device is equal to or more than about 10%.

9. The filter device according to claim 1, wherein the filter device is a band pass filter for Band N77 or Band N79.

10. The filter device according to claim 1, wherein the acoustic wave device is structured to generate a bulk wave in a thickness shear mode.

11. The filter device according to claim 1, wherein d/p is equal to or less than about 0.24.

12. The filter device according to claim 1, wherein a region where the electrode fingers that are adjacent to each other, of the plurality of electrode fingers, overlap each other when viewed in a direction in which the electrode fingers face each other is an excitation region, and when a metallization rate of the plurality of electrode fingers with respect to the excitation region is defined as MR, a condition of MR about 1.75 (d/p)+0.075 is satisfied.

13. The filter device according to claim 1, wherein the piezoelectric layer is a lithium tantalate layer or a lithium niobate layer.

14. The filter device according to claim 1, wherein Euler angles (φ, θ, ψ) of the lithium niobate or the lithium tantalate are within a range defined by Expression (1), Expression (2), or Expression (3):
(0°±10°,0° to 20°, freely selected ψ) Expression(1);
(0°±10°,20° to 80°,0° to 60°(1−(θ−50)²/900)^{1/2}) or (0°±10°,20° to 80°,[180°−60°(1−(θ−50)²/900)^{1/2}] to)180° Expression(2); and
(0°±10°, [180°−30° (1−(ψ−90)²/8100)^{1/2}] to 180°, freely selected ψ) Expression (3).

15. The filter device according to claim 1, wherein the first series arm resonator has a fractional band width is equal to or more than about 8%.

16. The filter device according to claim 1, wherein a fractional band width of the filter device is equal to or more than about 10%.

17. The filter device according to claim 1, wherein a thickness of the piezoelectric layer is equal to or more than about 40 nm and equal to or less than about 1000 nm.

18. The filter device according to claim 1, wherein a thickness of the piezoelectric layer is equal to or more than about 50 nm and equal to or less than about 1000 nm.

19. The filter device according to claim 1, wherein a pitch between the first electrode and the second electrode adjacent to each other is equal to or more than about 1 μm and equal to or less than about 10 μm.

20. The filter device according to claim 1, wherein an insulating layer is interposed between the support and the piezoelectric layer.
